(19) United States
(12) Patent Application Publication
(10) Pub. No.: US 2011/0061722 A1
(43) Pub. Date: Mar. 17, 2011

(54) DYE-SENSITIZED SOLAR CELL AND MANUFACTURING METHOD OF THE SAME

(76) Inventors: Seunghoon Ryu, Bucheon-si (KR); Kiyong Kim, Gwacheon-si (KR); Seongkee Park, Goyang-si (KR); Sunghoon Joo, Paju-si (KR)

(21) Appl. No.: 12/872,785

(22) Filed: Aug. 31, 2010

(30) Foreign Application Priority Data
Sep. 8, 2009 (KR) 10-2009-0084619

(51) Int. Cl. H01L 31/02; H01L 33/44

(52) U.S. Cl. 136/252; 438/57; 257/E33.06

(57) ABSTRACT

A dye-sensitized solar cell is disclosed. The dye-sensitized solar cell comprises a first substrate including a first electrode, a photo-absorption layer positioned on the first substrate, and a second substrate positioned on the photo-absorption layer and including a second electrode, the photo-absorption layer including a first scattering layer positioned in an area close to the second electrode.

This application claims the benefit of Korea Patent Application No. 10-2009-0084619, filed on Sep. 8, 2009, the entire contents of which is incorporated herein by reference for all purposes as if fully set forth herein.

### BACKGROUND

1. Field of the Invention

This disclosure relates to dye-sensitized solar cell. More specifically, the present disclosure relates to high-efficiency dye-sensitized solar cell and a manufacturing method for the same.

2. Discussion of the Related Art

Various researches are being conducted in search for a substitute for fossil fuels to resolve the imminent energy crisis. In particular, to substitute for oil resources to be exhausted in a few decades from now, researchers are focusing on how to utilize natural resources such as wind, atomic, and solar energy.

Different from the other potential substitutes, a solar cell is eco-friendly, making use of unlimited solar energy. A solar cell is, therefore, receiving wide-acceptance since the development of Si solar cell in 1983, particularly due to the recent energy crisis.

However, the manufacturing cost of silicon solar cells is high due to severe international competition caused by demand and supply problem of silicon as a raw material. To resolve the problem, many research organizations domestic or foreign proposed self-rescue plans. Difficulties still remain, however, to actually implement the plans. One of the alternative solutions to resolve the serious energy crisis is a dye-sensitized solar cell; ever since a research team headed by Dr. Micheal Graetzel of EPFL, of Switzerland developed the dye-sensitized solar cell in 1991, the academic society has paid much attention thereto and many research organizations have been conducting researches for the dye-sensitized solar cell.

Different from silicon-based solar cell, the dye-sensitized solar cell is an opto-electrochemical solar cell whose primary ingredients comprise photosensitive dye molecules that can generate electron-hole pairs by absorbing visible light and transition metal oxide that transfers the generated electrons. Dye-sensitized solar cells utilizing nano-particle titanium oxide are regarded as a typical research outcome among the previous research works for dye-sensitized solar cells.

The manufacturing cost of dye-sensitized solar cell is lower than the conventional silicon solar cell. What is more, dye-sensitized solar cell can be used for the windows of outer walls of a building or a glasshouse due to the transparent electrodes thereof. More researches are needed, however, because of the low efficiency of photoelectric transformation.

The efficiency of photoelectric transformation of solar cell is proportional to the number of electrons generated by absorption of sunlight. To increase the efficiency, therefore, increasing the number of generated electrons by increasing the amount of dye absorbed by titanium oxide nano-particles, increasing absorption of sunlight, and preventing generated excited-electrons from being annihilated by electron-hole recombination are required.

To increase the rate of dye absorption for a unit area, particles of oxide semiconductor are required to be fabricated in a nanometer scale. To that ends, a manufacturing method of increasing reflectivity of platinum electrodes to facilitate absorption of sunlight or a method of mixing the particles with optical scattering material made from oxide semiconductor has been developed.

The previous methods, however, have revealed limitation to increasing the efficiency of photoelectric transformation. Accordingly, development of a new technology for enhancing the efficiency is highly demanded.

### BRIEF SUMMARY

An aspect of dye-sensitized solar cell according to one embodiment of this invention comprises a first substrate including a first electrode, a photo-absorption layer positioned on the first substrate, and a second substrate positioned on the photo-absorption layer and including a second electrode, the photo-absorption layer including a first scattering layer positioned in an area close to the second electrode.

### BRIEF DESCRIPTION OF THE DRAWINGS

The accompany drawings, which are included to provide a further understanding of the invention and are incorporated on and constitute a part of this specification illustrate embodiments of the invention and together with the description serve to explain the principles of the invention.

FIG. 1 illustrates dye-sensitized solar cell according to a first embodiment of this invention;

FIGS. 2A to 2C illustrate cross sectional views of the respective processes comprising a method for manufacturing dye-sensitized solar cell according to a first embodiment of this invention;

FIG. 3 illustrates dye-sensitized solar cell according to a second embodiment of this invention;

FIGS. 4A to 4D illustrate cross sectional views of the respective processes comprising a method for manufacturing dye-sensitized solar cell according to a second embodiment of this invention;

FIG. 5 illustrates dye-sensitized solar cell manufactured according to a comparative example of this invention; and

FIG. 6 illustrates a current-voltage curve of dye-sensitized solar cell manufactured according to an embodiment and a comparative example of this invention.

### DETAILED DESCRIPTION OF THE DRAWINGS AND THE PRESENTLY PREFERRED EMBODIMENTS

Reference will now be made in detail embodiments of the invention examples of which are illustrated in the accompanying drawings.

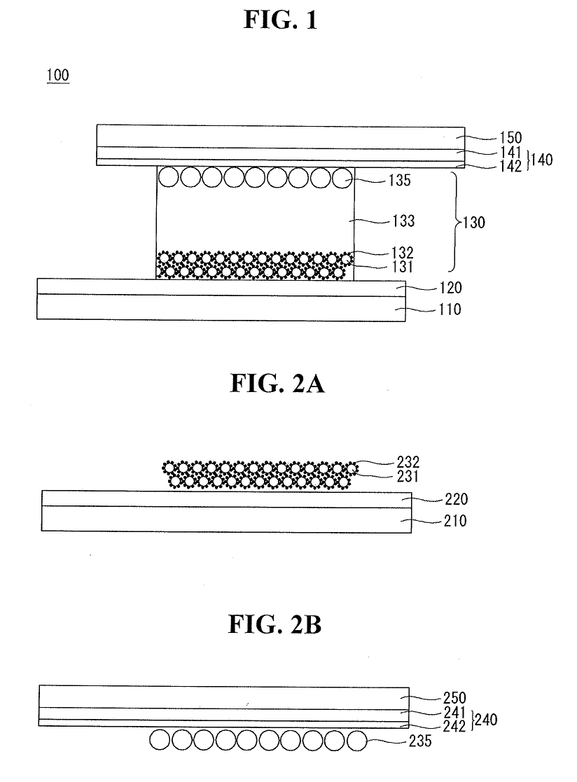

FIG. 1 illustrates dye-sensitized solar cell according to a first embodiment of this invention.

With reference to FIG. 1, dye-sensitized solar cell 100 according to a first embodiment of this invention comprises a first substrate 110 including a first electrode 120, a photo-absorption layer 130 positioned on the first substrate 110, and a second substrate 150 positioned on the photo-absorption layer 130 and including a second electrode 140, the photo-absorption layer 130 including a first scattering layer 135 positioned in an area close to the second electrode 140.

Dye-sensitized solar cell 100 has sandwich structure where a first electrode 120 and a second electrode 140 are joined together facing each other. More specifically, a first electrode 120 is positioned on a first substrate 110 and a second electrode 140 is facing the first electrode 120, the second electrode 140 positioned on a second substrate 150 that faces directly the first electrode 120.

Between the first electrode 120 and the second electrode 140, a photo-absorption layer 130 can be positioned, where the photo-absorption layer 130 includes semiconductor particles 131, dye 132 absorbed in the semiconductor particles 131, and electrolyte 133.

The first substrate 110 can be made of glass or plastic but any material can be employed if the material possesses transparency that enables incidence of external light.

A specific example of plastic can be polyethyleneterephthalate (PET), polyethylenenaphthalate (PEN), polycarbonate (PC), polypropylene (PP), polyimide (PI), triacetylcellulose (TAC), or copolymer thereof.

The first electrode 120 can include conductive metal oxide.

At this time, conductive metal oxide can be at least one selected from a group consisting of indium tin oxide (ITO), fluoride tin oxide (FTO), ZnO—(Ga₂O₃ or Al₂O₃), Sn-based oxide, antimonide tin oxide (ATO), zinc oxide (ZnO), and a compound thereof, preferably, F:SnO₂.

A photo-absorption layer 130 can include semiconductor particles 131, dye 132 absorbed in the semiconductor particles 131, and electrolyte 133.

The semiconductor particles 131 can use compound semiconductor or a compound of Perovskite structure as well as single element semiconductor represented by silicon.

The semiconductor can be n-type semiconductor that provides anode current by employing electrons in conduction band as carriers under optical excitation. The compound semiconductor can use metal oxide at least one selected from a group consisting of titan (Ti), tin (Sn), zinc (Zn), tungsten (W), zirconium (Zr), gallium (Ga), Indium (In), yttrium (Yr), niobium (Nb), tantalum (Ta), and vanadium (V). Preferably, the compound semiconductor can use titan oxide (TiO₂), tin oxide (SnO₂), zinc oxide (ZnO), niobium oxide (Nb₂O₅), titan strontium oxide (TiSrO₃), or compound thereof. More preferably, the compound semiconductor can use titan oxide (TiO₂) of anatase type. Types of the semiconductor are not limited to those above but a single type or combination of more than two types can be used.

Also, an average particle size of semiconductor particles 131 can range from 1 nm to 500 nm, preferably from 1 nm to 100 nm. Semiconductor particles 131 can use a combination of large and small sized particles or form a multi-layer thereof.

Semiconductor particles 131 can be manufactured in various ways: forming a thin film of semiconductor particles 131 by spraying them directly on a substrate; deposing electrically a thin film of semiconductor particles by using substrates as electrodes; or spreading paste obtained by hydrolyzing slurry of semiconductor particles or precursor of semiconductor particles on a substrate with subsequent drying, hardening, and plastic deformation.

On the surface of the semiconductor particles 131, dye 132 that absorbs external light and generates excited electrons can be adsorbed.

The dye 132 can be formed as a metal composite including aluminum (Al), platinum (Pt), palladium (Pd), europium (Eu), lead (Pb), iridium (Ir), and ruthenium (Ru). In particular, since ruthenium (Ru), an element belonging to platinum group, can form various organometallic compounds, it is desirable to use dye 132 containing ruthenium (Ru).

As an example of dye 132 containing ruthenium (Ru), Ru(etcbpy)₂(NCS)₂.CH₃CN type is used frequently. In this case, etc corresponds to (COOEt)₂ or (COOH)₂; and is a reactor that can be combined with the surface of porous membrane.

On the other hand, dye containing organic colorant can be used. For organic colorant, coumarin, porphyrin, xanthenes, riboflavin, or triphenylmethan can be used individually or combined with other composite.

The electrolyte 133 can use redox electrolyte. More specifically, the electrolyte 133 can use halogen oxidation and reduction electrolyte composed of halogen compound with halogen ion as large ion and halogen molecules; metal oxidation and reduction electrolyte such as metal complex including ferrocyanide-ferrocyanide, ferrocene-ferrocenium ion, and cobalt complex; and organic oxidation and reduction electrolyte such as alkylthiol-alkyldisulphide, viologen dye, and hydroquinone-quinone, preferably, halogen oxidation and reduction electrolyte.

As for halogen molecules related to halogen oxidation and reduction electrolyte composed of halogen compound-halogen molecules, iodine molecules are preferred. Also, as for halogen compound with halogen ion as large ion, metal salt halide such as LiI, NaI, CaI₂, MgI₂, and CuI; organic ammonium salt halide such as tetra-alkylammonium iodine, imidazolium iodine, and pyridinium iodine; or I₂ can be used.

If redox electrolyte is in the form of solution that contains the same, a solvent electrochemically inactive can be employed. More specific examples include acetonitrile, propylene carbonate, ethylene carbonate, 3-methoxypropionitrile, methoxyacetonitrile, ethylene glycol, propylene glycol, diethylene glycol, triethylene glycol, butyrolactone, dimethoxyethane, dimethyl carbonate, 1,3-dioxolane, methyl formate, 2-methyltetrahyrofuran, 3-methoxy-oxazolidine-2-on, sulfolane, tetrahydrofuran, and water. In particular, acetonitrile, propylene carbonate, ethylene carbonate, 3-methoxypropionitrile, ethylene glycol, 3-methoxy-oxazolidine-2-on, and butyrolactone are preferred. The aforementioned solvents can be used individually or being mixed with others.

The photo-absorption layer 130 can include a first scattering layer 135.

A first scattering layer 135 can operate as a transfer path for electrons excited from dye 132 when light penetrates through a first substrate 110.

To that ends, a first scattering layer 135 can be positioned close to a second electrode 140 and include a plurality of conductive particles.

The conductive particle can be made of metal oxide selected from a group consisting of titan (Ti), tin (Sn), zinc (Zn), tungsten (W), zirconium (Zr), gallium (Ga), Indium (In), yttrium (Yr), niobium (Nb), tantalum (Ta), and vanadium (V). Also, particle size of the conductive particle can range from 100 nm to 1000 nm.

The operating principle of solar cell is that electrons are excited as external light is absorbed in dye and the excited electrons are injected to a first electrode through semiconductor particles, generating current. Degradation of photo-electric transformation efficiency is caused by the difference of electron transfer efficiency between the respective interfaces of contacting components, particularly between individual electrodes and electrolyte.

In an embodiment of this invention, therefore, as a first scattering layer 135 operates as a transfer path through which electrons can move more easily than in electrolyte, transfer efficiency of electrons regenerated to semiconductor particles through electrolyte in a second electrode 140 can be enhanced.

A second substrate 150 including a second electrode 140 can be positioned on the photo-absorption layer 130.

A second electrode 140 can include a transparent electrode 141 and a catalytic electrode 142. The transparent electrode 141 can be formed by transparent material such as indium tin oxide, fluorine tin oxide, antimony tin oxide, zinc oxide, tin oxide, or ZnO—(Ga₂O₃ or Al₂O₃).

The catalytic electrode 142 activates an oxidation and reduction (redox) couple and can use conductive material such as platinum, gold, ruthenium, palladium, rhodium, iridium, osmium, carbon, titan oxide, and conductive polymer.

It is preferable for the catalytic electrode 142, which is facing the first electrode 120 to enhance catalytic effect of oxidation and reduction, to enlarge the surface area thereof by employing micro structure. For example, lead or gold is preferred to remain in black state, while carbon is preferred to remain in porous state. In particular, platinum in black state can be formed by applying anodic oxidation method or chloroplatinic acid treatment, while carbon in porous state can be formed by sintering of carbon particles or calcination of organic polymer.

The second substrate 150 can be made of glass or plastic in the same way as the foregoing first substrate 110. A specific example of plastic can be polyethyleneterephthalate (PET), polyethylenenaphthalate (PEN), polycarbonate (PC), polypropylene (PP), polyimide (PI), or triacetylcellulose (TAC).

If the dye-sensitized solar cell 100 is exposed to sunlight, photons are first absorbed in the dye 132 within the photo-absorption layer 130. Accordingly, dye 132 generates electron-hole pairs by electronic transition from ground state to excited state and electrons in excited state are injected to the conduction band of the contacting surface of semiconductor particles 131. Injected electrons transfer to the first electrode 120 through the contacting surface and subsequently move to the second electrode 140, the opposite electrode, through an external circuit.

Meanwhile, the dye 132 oxidized by electron transition is reduced by ions of oxidation-reduction couples within electrolyte 133. The oxidized ions carry out a reduction response with electrons arrived at the contacting surface of the second electrode 140 to attain charge neutrality, leading to the operation of the dye-sensitized solar cell 100.

In what follows, a method of manufacturing dye-sensitized solar cell according to the first embodiment of this invention is described.

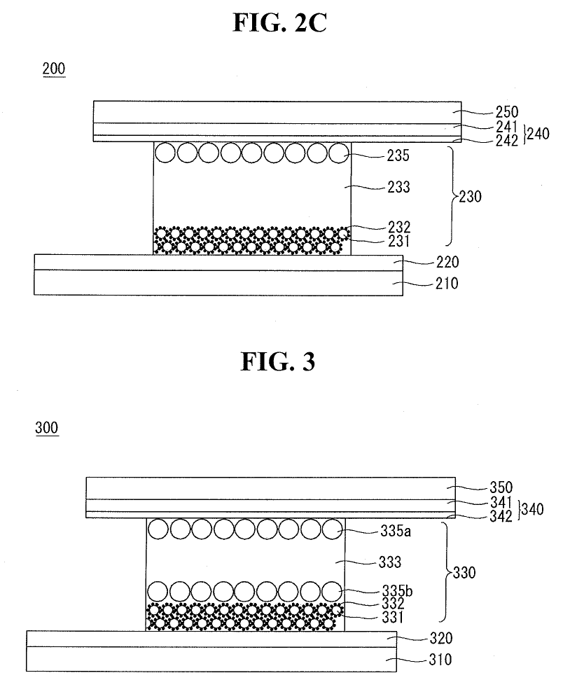

FIGS. 2A to 2C illustrate cross sectional views of the respective processes comprising a method for manufacturing dye-sensitized solar cell according to the first embodiment of this invention.

With reference to FIG. 2A, a first electrode 220 is formed on a first substrate 210. As described above, a first substrate 210 can use glass or plastic and a first electrode 220 can also use the aforementioned material. For example, the first electrode 220 can be fabricated by forming a conduction layer including conductive material on a transparent glass by using a physical vapor deposition (PVD) method such as electroplating, sputtering, and E-beam deposition; and by doping the conduction layer with fluorine (F).

Subsequently, semiconductor particles 231 including dye 232 are formed on the fabricated first electrode 220.

To describe in more detail, semiconductor particle paste is coated on the first electrode 220, the semiconductor particle paste being made by dispersing semiconductor particle, binder, and polymer for forming pores in a solvent.

At this time, semiconductor particle can use the same material as described above. Binder can use polyvinylidene fluoride, poly hexafluoropropylene-polyvinylidene fluoride copolymer, polyvinyl acetate, alkylated polyethylene oxide, polyvinyl ether, poly alkylmetaacrylate, poly tetrafluoroethylene, poly vinylchloride, poly acrylonitrile, poly vinylpyridine, styrene-butadiene rubber, copolymer thereof, or combination thereof.

The polymer for forming pores can use polymer that does not leave organic material after a heating process. For example, the polymer can use polyethylene glycol, polyethylene oxide, polyvinyl alcohol, or polyvinyl pyrrolidone.

The solvent can use alcohol such as ethanol, isopropyl alcohol, n-propyl alcohol, or butyl alcohol; water, dimethylacetamide, dimethylsulfoxide, or N-methylpyrrolidone.

A semiconductor particle paste coating method can use screen printing, spray coating, doctor blade, gravure coating, dip coating, silk screening, painting, slit die coating, spin coating, roll coating, or transcription coating.

A heating process is applied after the semiconductor particle paste is coated.

The heating process is carried out for 30 minutes or so at the temperature ranging from 400° C. to 600° C. when binder has been added to the paste. Otherwise, the heating process can be carried out at the temperate lower than 200° C.

Next, dye 232 is adsorbed on the semiconductor particle film formed by the heating process either by spraying dispersion containing the dye 232 on the semiconductor particle film, thus spreading the dispersion thereon or soaking the semiconductor particle film in immersion liquid.

Adsorption of the dye 232 can be finished about 12 hours later after a first substrate where semiconductor particle film has been formed is immersed in the dispersion that contains the dye 232. Time needed for adsorption can be shortened by applying heating. At this time, the aforementioned material can be used for dye; and acetonitrile, dichloromethane, or alcohol-based solvent can be used for the solvent that disperses dye.

Semiconductor particles 231 on which dye 232 has been adsorbed can be formed by solvent cleaning after the dye adsorption process.

Next, with reference to FIG. 2B, a second substrate 250 including a second electrode 240 is formed.

To describe in more detail, transparent electrode 241 is formed by forming a conduction layer including conductive material on a transparent second substrate 250 composed of glass or plastic by using a physical vapor deposition (PVD) method such as electroplating, sputtering, and E-beam deposition; and by doping the conduction layer with fluorine (F).

Next, the transparent electrode 241 is coated with catalyst precursor solution dissolved in a solvent such as alcohol and then forms electrocatalyst 242 after receiving high temperature heat treatment at more than 400° C. degrees in the air or oxygen.

Next, a first scattering layer 235 is formed on a second substrate 250 where the second electrode 240 has been formed.

To describe in more detail, paste is formed by dispersing a plurality of conductive particles composed of metal oxide, binder, and polymer for forming pores in a solvent. The conductive particle can be made of metal oxide at least one selected from a group consisting of titan (Ti), tin (Sn), zinc (Zn), tungsten (W), zirconium (Zr), gallium (Ga), Indium (In), yttrium (Yr), niobium (Nb), tantalum (Ta), and vanadium (V); binder, polymer for forming pores, and solvent can use the same material as semiconductor particle paste described above.

A first scattering layer 235 is formed by coating the manufactured paste by using a method selected from a group consisting of screen printing, spray coating, doctor blade, dip coating, silk screening, painting, slit die coating, spin coating, roll coating, and transcription coating.

A heating process is carried out after the first scattering layer 235 has been formed. The heating process is carried out for 30 minutes or so at the temperature ranging from 400° C. to 600° C. when binder has been added. Otherwise, the heating process can be carried out at the temperature lower than 200° C.

Next, with reference to FIG. 2C, the first substrate 210, the middle layer 230, and the second substrate 250 formed as described above are joined together facing each other. More specifically, adhesive such as thermoplastic polymer film, epoxy resin, or ultraviolet hardener can be used for joining the surfaces together.

Fine holes that penetrate the second substrate 250 are formed and electrolyte 233 is injected through the holes to the space between both electrodes. At this time, electrolyte 233 can use the material described above.

Finally, the holes formed in the second substrate 250 after electrolyte 233 has been injected are sealed hermetically by adhesive, thus accomplishing dye-sensitized solar cell 200 according to one embodiment of this invention.

FIG. 3 illustrates dye-sensitized solar cell according to a second embodiment of this invention.

With reference to FIG. 3, dye-sensitized solar cell 300 according to a second embodiment of this invention comprises a first substrate 310 including a first electrode 320, a photo-absorption layer 330 positioned on the first substrate 310, and a second substrate 350 positioned on the photo-absorption layer 330 and including a second electrode 340, the photo-absorption layer 330 including a first scattering layer 335A positioned in an area close to the second electrode 340 and a second scattering layer 335B positioned in an area close to the first electrode 320.

Structure of dye-sensitized solar cell 300 according to a second embodiment of this invention corresponds to that of dye-sensitized solar cell 300 according to the first embodiment described above with a second scattering layer 335B further included; therefore, description of the same structure as in the first embodiment will not be provided.

A second scattering layer 335B is positioned on semiconductor particles 331 to which dye of the photo-absorption layer 330 has been adsorbed, positioned in an area close to the first electrode 320.

The second scattering layer 335B is made of conductive particles in the same way as the first scattering layer 335B described above. Particle size of conductive particles can range from 100 nm to 1000 nm.

In the same way as the first scattering layer 335A, the second scattering layer 335B operates as a transfer path through which electrons can move more easily than in electrolyte; therefore, transfer efficiency of electrons regenerated to semiconductor particles through electrolyte in a second electrode 340 can be enhanced.

In other words, dye-sensitized solar cell according to a second embodiment of this invention comprises a first scattering layer in an area close to a second electrode and further comprises a second scattering layer in an area close to a first electrode, namely on semiconductor particles, thus enhancing electron transfer efficiency by forming a transfer path for electrons to move easily.

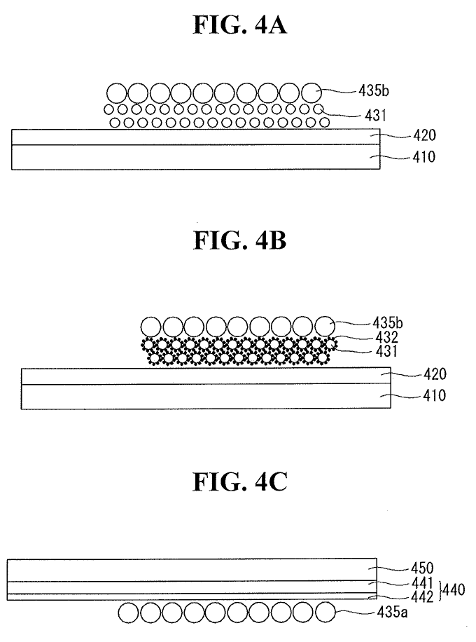

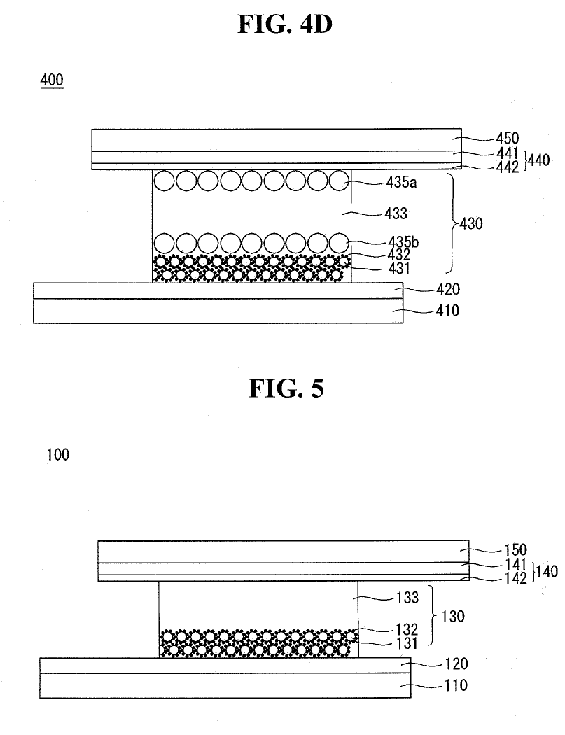

In what follows, with reference to FIGS. 4A to 4D, dye-sensitized solar cell according to a second embodiment of this invention is described. However, descriptions of the same processes as those of the first embodiment described above will not be provided.

First, with reference to FIG. 4A, a first electrode 420 is formed on a first substrate 410. Next, semiconductor particles 431 including dye 432 are formed on the fabricated first electrode 420.

To describe in more detail, semiconductor particle paste is spread on the first electrode 420, the semiconductor particle paste being made by dispersing semiconductor particle, binder, and polymer for forming pores in a solvent. A heating process is applied after the semiconductor particle paste is spread.

Next, a second scattering layer 435B is formed by dispersing a plurality of conductive particles in binder, polymer for forming pores, and a solvent and spreading them on semiconductor particles 431 formed by the heating process. The conductive particle can be made of metal oxide at least one selected from a group consisting of titan (Ti), tin (Sn), zinc (Zn), tungsten (W), zirconium (Zr), gallium (Ga), Indium (In), yttrium (Yr), niobium (Nb), tantalum (Ta), and vanadium (V); binder, polymer for forming pores, and solvent can use the same material as semiconductor particle paste described above.

A second scattering layer 435B is formed by coating the manufactured paste by using a method selected from a group consisting of screen printing, spray coating, doctor blade, dip coating, silk screening, painting, slit die coating, spin coating, roll coating, and transcription coating.

A heating process is carried out after the second scattering layer 435B has been formed. The heating process is carried out for 30 minutes or so at the temperature ranging from 400° C. to 600° C. when binder has been added. Otherwise, the heating process can be carried out at the temperature lower than 200° C.

Next, with reference to FIG. 4B, dye 432 is adsorbed on the semiconductor particle 431 either by spraying dispersion containing the dye 232 on the first substrate 410 where semiconductor particle 431 and the second scattering layer 435B have been formed, thus spreading the dispersion thereon or soaking the semiconductor particle 431 in immersion liquid. At this time, dye 432 is adsorbed on semiconductor particle 431 with a small particle size, passing through the second scattering layer 435B with a large particle size.

Adsorption of the dye 432 can be finished about 12 hours later after a first substrate where semiconductor particle film has been formed is immersed in the dispersion that contains the dye 432. Time needed for adsorption can be shortened by applying heating. At this time, the aforementioned material can be used for dye; and acetonitrile, dichloromethane, or alcohol-based solvent can be used for the solvent that disperses dye.

Semiconductor particles 431 on which dye 432 has been adsorbed can be formed by solvent cleaning after the dye adsorption process.

Next, with reference to FIG. 4C, a second substrate 450 including a second electrode 440 is formed.

To describe in more detail, a transparent electrode 441 is formed by forming a conduction layer including conductive material on a transparent second substrate 450 composed of glass or plastic by using a physical vapor deposition (PVD) method such as electroplating, sputtering, or E-beam deposition; and by doping the conduction layer with fluorine (F).

Next, the transparent electrode 441 is coated with catalyst precursor solution dissolved in a solvent such as alcohol and then forms electrocatalyst 242 after receiving high temperature heat treatment at more than 400° C. degrees in the air or oxygen.

Next, a first scattering layer 435A is formed on a second substrate 450 where the second electrode 440 has been formed. A method for forming a first scattering layer 435A is the same as the method for forming the second scattering layer 435B described above.

Next, with reference to FIG. 4D, the first substrate 410, the middle layer 430, and the second substrate 450 formed as described above are joined together facing each other. More specifically, adhesive such as thermoplastic polymer film, epoxy resin, or ultraviolet hardener can be used for joining the surfaces together.

Fine holes that penetrate the second substrate 450 are formed and electrolyte 433 is injected through the holes to the space between both the electrodes. At this time, electrolyte 2433 can use the material described above.

Finally, the holes formed in the second substrate 450 after electrolyte 433 has been injected are sealed hermetically by adhesive, thus accomplishing dye-sensitized solar cell 400 according to one embodiment of this invention.

Hereinafter, preferred embodiments of this invention will be described. The embodiments in the following are provided for the illustration purpose only and thus, this invention is not limited to the following embodiments.

### Embodiment

### Manufacturing of Dye-Sensitized Solar Cell

(1) Manufacturing Working Electrode

FTO glass (Fluorine-doped tin oxide coated conduction glass, Pilkington, TEC7) is cut by the size of 1.5 cm×1.5 cm and undergoes sonication cleaning for 10 minutes by using glass detergent; suds are completely removed by using distilled water. Next, sonication cleaning is repeated two times for 15 minutes by using ethanol. FTO glass is washed out completely by using ethanol absolute and dried in the oven at temperature of 100° C. To increase contact force against TiO₂, the FTO glass prepared through the above procedure is immersed in 40 mM titanium (IV) chloride solution of 70° C. for 40 minutes and washed out by using distilled water and dried completely in the oven at the temperature of 100° C. Next, titania (TiO₂) paste (18-NR) manufactured by CCIC Inc. is employed for dye and is coated on the FTO glass by using a screen printer and 9 mm×9 mm mask (200 meshs). Coated film is dried in the oven of 100° C. for 20 minutes, which is repeated three times. Titania (TiO₂) paste (400C) manufactured by CCIC Inc. is coated once on the obtained TiO₂ film by using a screen printer and the coated TiO₂ film is dried in the oven of 100° C. for 20 minutes. Subsequently, coated film undergoes plastic working at the temperature of 450° C. for 60 minutes, thereby obtaining TiO₂ film of about 13 μm thickness. Dye is absorbed by immersing TiO₂ film after the heating process in the anhydrous ethanol solution of synthetic dye of 0.5 mM density for 24 hours. After adsorption, remaining dye not adsorbed in anhydrous ethanol is washed out completely and dried by using a heat gun.

(2) Manufacturing Counter Electrode

Two holes through which electrolyte can pass are generated in the FTO glass of 1.5 cm×1.5 cm size by using φ0.7 mm diamond drill (Dremel multipro395). Next, the FTO glass is washed out in the same way used for working electrode and dried. Subsequently, the FTO glass is coated with hydrogen hexachloroplatinate (H₂PtCl₆) 2-propanol solution; the FTO glass then undergoes plastic working for 60 minutes at the temperature of 450° C. Next, in the same way for manufacturing working electrode, titania (TiO₂) paste (400C) manufactured by CCIC Inc. is coated once on the obtained TiO₂ film by using a screen printer and the coated TiO₂ film is dried in the oven of 100° C. for 20 minutes. Subsequently, coated film undergoes plastic working at the temperature of 450° C. for 60 minutes, thereby obtaining TiO₂ film of about 13 μm thickness.

(3) Manufacturing Sandwich Cell

Surlyn (SX1170-25 Hot Melt) cut in the shape of a rectangular belt is put between the working electrode and counter electrode; the two electrodes are bonded together by using a clip and an oven; and electrolyte is injected through two small holes prepared in the counter electrode. Sandwich cell is then manufactured by sealing therewith surlyn strip and a cover glass. At this time, electrolyte solution is made by using 0.1M LiI, 0.05M I2, 0.6M 1-hexil-2,3-dimethylimideazolium iodide and 0.5M 4-tert-butylpyridine with 3-metoxypropionitrile as solvent.

(5) Photocurrent-Voltage Measurement

Light from Xe lamp (Oriel, 300 W Xe arc lamp) equipped with AM 1.5 solar simulating filter is applied on the sandwich cell manufactured above. Current-voltage curve is obtained by using M236 source measure unit (SMU, Keithley). The range of electric potential is from −0.8V to 0.2V and the intensity of light is set at 100 W/cm².

### A Comparative Example

Dye-sensitized solar cell of FIG. 5 is manufactured by using the same process conditions except for the process of forming TiO₂ film by screen printing of titania (TiO₂) paste (400C) manufactured by CCIC Inc. applied for manufacturing counter electrode and working electrode of the embodiment described above. (FIG. 5 uses the same drawing symbols for the corresponding elements of FIG. 1 and descriptions thereof are not provided.)

Short-circuit photocurrent density (Jsc), open circuit voltage (Voc), fill factor (FF), photo-electric transformation efficiency (PCE) of dye-sensitized solar cell manufactured according to the embodiment and the comparative example are measured. Table 1 and FIG. 5 illustrate the measurement data. At this time, the embodiments and the comparative example have been measured twice under the same conditions.

TABLE 1

| | # | Area(□) | Jsc(□) | Voc(V) | FF(%) | PCE(%) |
|---|---|---|---|---|---|---|
| Embodi- | 1 | 0.25 | 11.54963 | 0.701245 | 0.683551 | 5.536165 |
| ment | 2 | 0.25 | 11.47782 | 0.699638 | 0.687637 | 5.521944 |
| Compar- | 1 | 0.25 | 10.53632 | 0.695477 | 0.714066 | 5.232506 |
| ative | 2 | 0.25 | 10.59089 | 0.696056 | 0.711278 | 5.243437 |
| example | | | | | | |

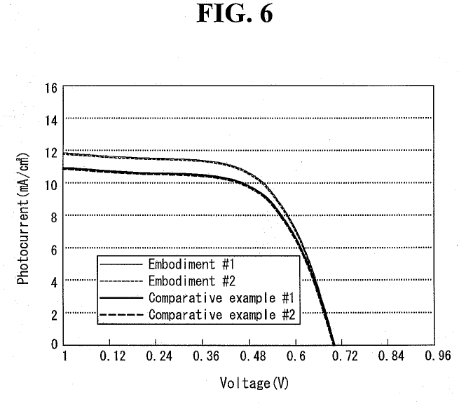

As shown in the Table 1 and FIG. 6, dye-sensitized solar cell manufactured according to the embodiment of this invention provides superior photo-electric transformation efficiency (PCE) to that of the comparative example.

Therefore, dye-sensitized solar cell according to one embodiment of this invention forms a middle layer containing a scattering layer, thereby providing excellent photo-electric transformation efficiency (PCE).

The foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures.

1. A dye-sensitized solar cell, comprising:
a first substrate including a first electrode;
a photo-absorption layer positioned on the first substrate; and
a second substrate positioned on the photo-absorption layer and including a second electrode, the photo-absorption layer including a first scattering layer positioned in an area close to the second electrode.

2. The dye-sensitized solar cell of claim 1, wherein the photo-absorption layer comprises electrolyte and a plurality of semiconductor particles including dye.

3. The dye-sensitized solar cell of claim 2, further comprising a second scattering layer between the semiconductor particles and the first scattering layer.

4. The dye-sensitized solar cell of claim 3, wherein the second scattering layer is positioned close to the second electrode.

5. The dye-sensitized solar cell of claim 3, wherein the first and the second scattering layer include a plurality of conductive particles.

6. The dye-sensitized solar cell of claim 5, wherein the conductive particle is made of metal oxide selected from a group consisting of titan (Ti), tin (Sn), zinc (Zn), tungsten (W), zirconium (Zr), gallium (Ga), Indium (In), yttrium (Yr), niobium (Nb), tantalum (Ta), and vanadium (V).

7. The dye-sensitized solar cell of claim 5, wherein particle size of the conductive particle ranges from 100 nm to 1000 nm.

8. A method for manufacturing dye-sensitized solar cell, comprising:
forming a first electrode on a first substrate;
forming a photo-absorption layer including semiconductor particles on the first electrode;
forming a first scattering layer on a second substrate including a second electrode; and
joining the first substrate and the second substrate together and injecting electrolyte into the photo-absorption layer.

9. The method of claim 8, wherein the forming a photo-absorption layer including the semiconductor particles comprises forming semiconductor particles on the first electrode, forming a second scattering layer on the semiconductor particles, and adsorbing dye on the semiconductor particles.

10. The method of claim 9, wherein the first and the second scattering layer are formed by using one selected from a group consisting of screen printing, spray coating, doctor blade, dip coating, silk screening, painting, slit die coating, spin coating, roll coating, and transcription coating method.
